(19) United States
(12) Patent Application Publication
(10) Pub. No.: US 2026/0254195 A1
(43) Pub. Date: Aug. 27, 2026

(54) LOW-NOISE EMITTER DEVICE, CONTROL LOOP, AND METHOD FOR OPERATING THE CONTROL LOOP

(71) Applicant: ARDA ATOMICS GMBH, Stuttgart (DE)

(72) Inventor: Peter Zwissler, Stuttgart (DE)

(21) Appl. No.: 19/489,745

(22) PCT Filed: Jun. 5, 2024
(86) PCT No.: PCT/EP2024/065459

§ 371 Date: Dec. 3, 2025

(30) Foreign Application Priority Data
Jun. 6, 2023 (DE) 10 2023 114 879.6

(51) Int. Cl. H01S 5/024; H01S 5/042; H01S 5/40

(52) U.S. Cl. CPC H01S 5/02415; H01S 5/02438; H01S 5/042; H01S 5/4025

(57) ABSTRACT

An emitter device is provided that includes a plurality of emitters, a plurality of current drivers, and a plurality of thermoelectric cooling systems. Each emitter is associated with at least one current driver and at least one thermoelectric cooling system. The thermoelectric cooling systems are configured to regulate the temperature of at least one emitter and at least one current driver.

The invention relates to an emitter device according to claim 1, to a gyroscope according to claim 13, to a control loop according to claim 14, and to a method for operating the control loop according to claim 15.

In known emitter devices, a target value for the emitter current was fixed by means of a resistor. Changing the target value was achieved by manually desoldering the original resistor and manually inserting a different resistor. Furthermore, in other known emitter devices, a target temperature was achieved by controlled switching on and off of the emitter device, and the associated heating in the switched-on state and cooling in the switched-off state. Other emitter devices used a trim resistor or potentiometer to set the target temperature.

A disadvantage of the aforementioned prior art is that the known emitter devices are prone to malfunctions.

Proceeding from this, the present invention aims to provide an improved emitter device. A further object of the invention is to provide an improved gyroscope having such an emitter device. Furthermore, the invention is based upon the object of providing an improved control loop for such an emitter device and a method for operating the control loop.

This object is achieved by the present invention. The invention is defined by the objects having the features of the independent claims directed thereto. Advantageous embodiments and further developments of the invention are the subject of dependent claims and the following description.

The emitter device according to the invention and preferred developments thereof are preferably designed and provided for use in the gyroscope according to the invention, the control loop according to the invention, and the method according to the invention, as well as in preferred developments thereof.

All features of the items described here and also of the claimed items are usable both in isolation and in combination with each other, are compatible with each other and intended and usable for further development with each other, and are hereby disclosed accordingly, provided that no logical contradiction arises. The mere fact that certain features are mentioned in different claims does not mean that a combination of these features is not provided for and advantageous.

In the following, any reference to an object or feature (including the indefinite articles “a” and “an” and the definite article “the”), two objects or two features, or any other number of objects or features, unless expressly stated otherwise or a logical contradiction arises, shall be understood as meaning that the existence of further such objects and features is not excluded by the invention, but is also included by the invention. The words “comprising,” “having,” and “with” do not exclude further objects, features, elements, or steps. The reference signs in the claims are not to be understood as restrictive, but merely serve to improve the readability of the claims.

According to a first aspect of the invention, the emitter device has a plurality of emitters for emitting light. Furthermore, the emitter device features a large number of current drivers. The current drivers are designed and configured to supply electrical current to at least one of the emitters. The emitter device also includes a variety of TEC systems. The TEC systems are designed and configured to regulate the temperature of at least one of the emitters and, in particular, of at least one of the current drivers. In the emitter device, each individual emitter is assigned at least one of the current drivers and one of the TEC systems.

The “emitter” is preferably designed to emit light. In particular, the emitter emits light beams when an electric current is applied to it. Preferably, the emitter is a laser diode. Preferably, the emitter is an LED diode. The multitude of emitters includes, in particular, a first emitter and a second emitter. Preferably, the emitters of the multitude of emitters are identical in construction.

The “current driver” preferentially drives electric current through the emitter. Preferably, the current driver is a laser diode current driver. Preferably, the current driver is an LDO current driver. The multitude of current drivers includes, in particular, a first current driver and a second current driver. Preferably, the current drivers of the plurality of current drivers are identical in construction.

The “TEC system” comprises in particular a TEC controller and a TEC element. The TEC element is preferably a Peltier element. The TEC system regulates the temperature preferably by comparing a measured temperature with a set target temperature. Preferably, if there is a predetermined deviation of these temperatures, the TEC controller provides an adapted current to the TEC element. The multitude of TEC systems includes, in particular, a first TEC system and a second TEC system. Preferably, the TEC systems are identical in construction to the multitude of TEC systems.

According to a second aspect of the invention, the gyroscope comprises the emitter device. The “gyroscope” is preferably an atomic gyroscope, particularly preferably an atomic spin gyroscope. Preferably, the gyroscope has beam guidance optics, preferably with at least one mirror, through which the light beams are guided in such a way that they intersect.

According to a third aspect of the invention, the control loop for the emitter device comprises a PID controller. Furthermore, the control loop comprises a measuring resistor. The control loop also includes an instrumentation amplifier. In this control loop, at least one of the current drivers is located between the PID controller and the measuring resistor, and is thus electrically connected. Furthermore, the instrumentation amplifier is positioned between the PID controller and the measuring resistor, and is thus electrically connected.

The “PID controller” is preferably an integrator, and more preferably an integrator amplifier. Preferably, the PID controller is an operational amplifier. The “measuring resistor” is preferably an ohmic resistor, particularly preferably a precision resistor.

The “instrumentation amplifier” is preferably a precise operational amplifier circuit with high-impedance inputs, typically 10⁹Ω to 10¹²Ω. The “electrical connection” preferably establishes a permanent or detachable electrical contact between two elements and serves to conduct electric current.

According to a fourth aspect of the invention, the method for operating the control loop comprises the following steps:
providing the control loop;
arranging the measuring resistor between the current driver, the instrumentation amplifier, and the laser diode;
setting a voltage;
generating a control signal, especially for the PID controller;
providing the control signal to the current driver;
generating an emitter current for the current driver;
applying the emitter current to the emitter;
tapping the emitter current at the measuring resistor;
providing voltage to the instrumentation amplifier;
determining the voltage, in particular an actual voltage, at the instrumentation amplifier;
comparing the determined voltage, in particular the actual voltage, with the set voltage, in particular a target voltage;
adjusting the control signal according to the comparison.

Preferably, all steps of the procedure are performed simultaneously. “Setting the voltage” preferably involves specifying a target current by inputting a digital-to-analog converter voltage, which preferably corresponds to the target voltage. The emitter current is preferentially generated by the current driver. The actual voltage is, in particular, a measured voltage with an offset parameter. “Tapping the emitter current” is preferably carried out by determining the measured voltage with an offset parameter at the measuring resistor. The “determination of the voltage” preferably corresponds to providing the actual voltage as a measuring voltage by the instrumentation amplifier. Preferably, the control signal corresponds to the integrator voltage. Preferably, the control signal is a positioning signal. The “adjustment of the control signal” is preferably carried out by the PID controller depending upon the comparison.

Preferably, the emitter device comprises a plurality of circuit boards. Preferably, one of the emitters and the associated current drivers and TEC systems are arranged on each of the circuit boards. Alternatively, the TEC controller is preferably arranged on the circuit board, and the TEC element is attached to the emitter. The multitude of circuit boards includes, in particular, a first circuit board and a second circuit board. The “circuit board” is preferably a printed circuit.

Preferably, at least one of the TEC systems is in thermal contact with at least one of the emitters. Preferably, at least one of the TEC systems is arranged in thermal contact with at least one of the current drivers.

Particularly preferably, the TEC system, particularly preferably the TEC element, most preferably only the TEC element, is arranged in thermal contact with exactly one of the emitters and preferably exactly one of the current drivers.

Preferably, the TEC systems are designed and configured to keep the current drivers and/or the emitters at a constant temperature. Preferably, the constant temperature comprises a temperature deviation of 10 K to 0.01 K, particularly preferably of 5 K to 0.01 K, most preferably of 1 K to 0.01 K, and more preferably of 0.5 K to 0.01 K.

Preferably, the emitter device comprises a circuit board voltage source which is particularly preferably arranged on or with the first circuit board or comprised by the first circuit board.

The “circuit board voltage source” is preferably a linear regulator. A particularly preferred circuit board voltage source is an LT3045 linear regulator and/or an LT3094 linear regulator. Preferably, the circuit board voltage source is designed to convert a supply voltage provided by an external power supply.

Preferably, the circuit board voltage source is designed and configured to supply current to all TEC systems and/or all current drivers.

Preferably, the emitter device comprises a controller, which is particularly preferably arranged on or with the second circuit board or comprised by the second circuit board. The “controller” is preferably a microcontroller. Preferably, the circuit board voltage source is designed and configured to supply current to the controller.

Preferably, the controller is arranged with a connection to a serial interface and/or has a serial interface. The “serial interface” is in particular a “universal asynchronous receiver transmitter” interface, or UART interface for short. The “controller” preferably receives the temperature and target current values via the serial interface from a PC or a server.

Preferably, the controller is designed and configured to control all TEC systems, in particular their TEC controllers and/or all current drivers.

Preferably, the circuit boards are arranged in a common housing.

The “housing” preferably does not include a switched-mode power supply. Preferably, the ±12 V for supplying the circuit board voltage source is generated externally. In particular, the housing comprises an interlock safety shutdown, which preferably ensures that, if a person enters the room in which the emitter device is operated, it is automatically switched off.

Tests have shown that all of the aforementioned features and/or combinations of features result in multiple advantageous effects that contribute to the improvement of the emitter device, the gyroscope, the control loop, and the method for operating the control loop.

The first advantage is that a particularly compact and miniaturized design can be achieved, which is also easily adaptable to customer needs.

A second advantageous effect is that the plurality of emitters allows for a dual laser output—for example, with a probe laser and a pump laser.

A third advantageous effect is that particularly low-noise light can be generated from the emitters, especially by the preferred selection of low-noise current drivers and/or low-noise TEC systems and/or the low-noise circuit board voltage source.

A fourth advantage is that particularly high cooling efficiency can be achieved.

Advantageously, a target temperature value and/or a target current value can be defined and digitally entered by a user—for example, via a PC using the serial interface to the controller. This makes the control process significantly easier and faster. The faster control process allows, for example, a sweep to be performed, in which a plurality of values of a parameter, such as the target temperature value and/or the target current value, are periodically cycled through—i.e., entered and actuated—within a defined range.

It is understood that the subject matter of the independent claims or the foregoing description have similar and/or identical further developments and embodiments. In a preferred embodiment, any combination of the dependent claims and/or the features described in the description with the respective independent claim is provided.

Further properties and advantages of the invention ensue from the following description based upon exemplary embodiments and with reference to the drawings. Although the invention is shown and disclosed in detail in the figures and the preceding description, these illustrations and descriptions are to be regarded as purely illustrative or exemplary and not as limiting. It goes without saying that the above features and those to be explained below can be used not only in each specified combination, but also in other combinations or in isolation.

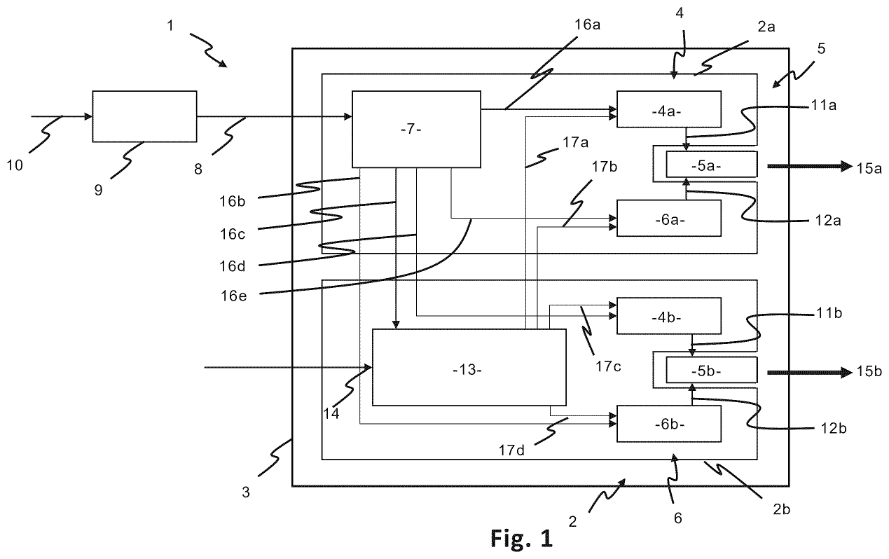

FIG. 1 shows an emitter device with two circuit boards;

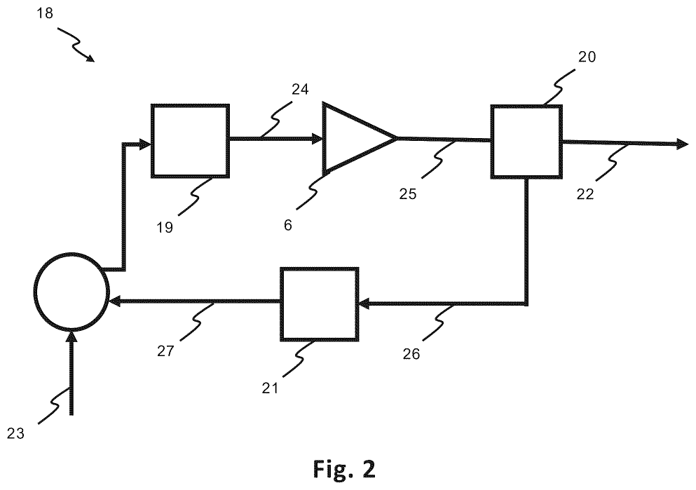

FIG. 2 shows a control loop;

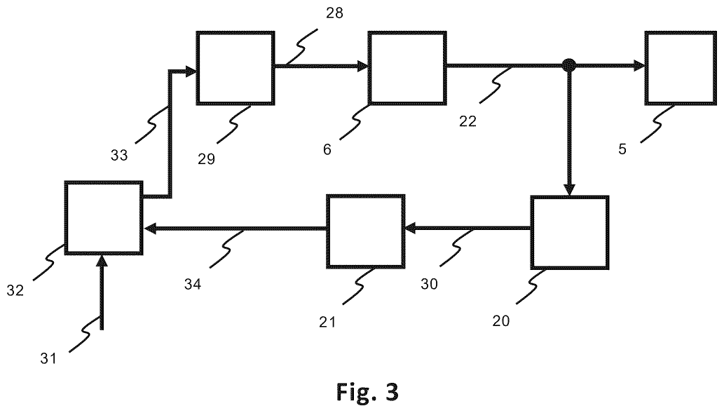

FIG. 3 shows a block diagram of the method for operating the control loop;

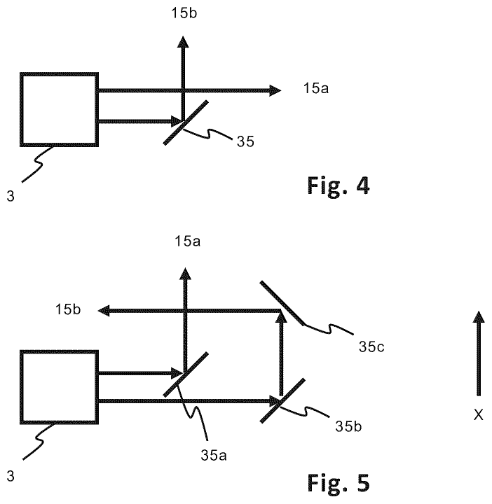

FIG. 4 shows a first exemplary embodiment of a beam path with a mirror;

FIG. 5 shows a second exemplary embodiment of a beam path with three mirrors.

The same reference signs used in the figures denote identical or at least equivalent elements. The terms “top,” “bottom,” “left,” and “right,” as well as direction-dependent information derived from them, such as “top side,” refer to the writing/reading direction of the figure designation “Fig.” belonging to a drawing, which is printed on the drawing plane below the drawing. The horizontal direction is parallel to the writing direction of “Fig.” and the vertical direction is perpendicular to the writing direction of “Fig.” The writing direction is a horizontal, right-handed script, i.e., primarily from left to right, as in Latin, English, French, and German.

FIG. 1 shows an emitter device 1 with a first circuit board 2a and a second circuit board 2b, which are arranged in a common housing 3. The first circuit board 2a includes a first TEC system 4a, a first emitter 5a, and a first current driver 6a. Furthermore, the first circuit board 2a comprises a circuit board voltage source 7, which is electrically connected via a current conductor 8 to an external voltage source 9, preferably with a switch. The voltage source 9, preferably with a switch, is connected to a power connection 10—for example, a 220 V power connection 10. The first emitter 5a is arranged in thermal contact 11a with the first TEC system 4a and can be supplied with electric current by the first current driver 6a, in particular via a first DC conductor 12a.

The second circuit board 2b includes a second TEC system 4b, a second emitter 5b, a second current driver 6b, and a controller 13. The controller 13 has a serial interface 14, which is designed as a UART interface 14. The UART interface 14 can be connected to an external PC and controlled via a UART signal. The second emitter 5b is arranged in thermal contact 11b with the second TEC system 4b and can be supplied with electric current by the second current driver 6b, in particular via a second DC conductor 12b. During operation, the first emitter 6a emits a first light beam 15a, and the second emitter 6b emits a second light beam 15b. Light beams 15a, 15b are in particular laser beams.

The circuit board voltage source 7 is designed to supply current to all components arranged on the circuit boards 2a, 2b. For this purpose, the circuit board voltage source 7 is connected to the first TEC system 4a via a first conductor track 16a, to the second current driver 6b via a second conductor track 16b, to the controller 13 via a third conductor track 16c, to the second TEC system 4b via a fourth conductor track 16d, and to the first current driver 6a via a fifth conductor track 16e.

The controller 13 is connected to the first TEC system 4a via a first control signal path 17a, to the first current driver 6a via a second control signal path 17b, to the second TEC system 4b via a third control signal path 17c, and to the second current driver 6b via a fourth control signal path 6b. The controller 13 is also intended for switching on and off the current drivers 6a, 6b when the corresponding control signal is given.

The emitters 5a, 5b are supplied with electric current via the associated current drivers 6a, 6b, wherein the electric current is provided, with low noise, by the circuit board voltage 7. The TEC systems 4a, 4b are in thermal contact with the emitters 5a, 5b arranged on the same circuit boards 2a, 2b, and preferably with the current drivers 6a, 6b. This allows the TEC systems 4a, 4b to regulate the temperature of these components and maintain them within a pre-set, constant temperature range. This precise temperature control allows the aforementioned components to be operated with particularly low noise.

FIG. 2 shows a control loop 18 with a PID controller 19—here, an integrator 19—a current driver 6, a measuring resistor 20, and an instrumentation amplifier 21. The current driver 6 is arranged between the integrator 19 and the measuring resistor 20, and the instrumentation amplifier 21 is arranged between the integrator 19 and the measuring resistor 20. The measuring resistor 20 is designed to supply the emitter 5a, 5b with an emitter current 22.

The integrator 19 is supplied with a digital-to-analog converter voltage 23 by a digital-to-analog converter (not shown here). The digital-to-analog converter voltage 23 corresponds to the output voltage of the digital-to-analog converter. During operation, an integrator voltage 24 is applied between the integrator 19 and the current driver 6. A current driver voltage 25 is applied between the current driver 6 and the measuring resistor 20. A measuring resistor voltage with an offset parameter 26 is applied between the measuring resistor 20 and the instrumentation amplifier 21. A measuring resistor voltage 27 is applied between the instrumentation amplifier 21 and the integrator 19.

The control loop 18 is designed such that, in the steady state, the measuring resistor voltage 27 is equal to the digital-to-analog converter voltage 23. The instrumentation amplifier 21 removes the offset parameter of the measuring resistor voltage with the offset parameter 26, which offset parameter is caused by the electronic components that are connected after the measuring resistor 20, in particular a measuring resistor 20 (not shown here) and the emitter 5a, 5b (not shown here).

The operational amplifier acts as an integrator 19 and compares the measuring resistor voltage 27 with the digital-to-analog converter voltage 23 of the digital-to-analog converter, and increases or decreases the integrator voltage 24 accordingly to compensate for the offset parameter. The current driver 6 can be considered a low-dropout linear regulator (LDO) and thus a unit buffer.

FIG. 3 shows a schematic block diagram of a method for operating the control loop 18 (shown in FIG. 2). First, the control loop 18 and a measuring resistor 20 are provided. Then, the measuring resistor 20 is placed between the current driver 6 and the instrumentation amplifier 21, and a voltage is set. In addition, a control signal 28 (corresponding to the integrator voltage 24) is generated by a control signal generator 29, in particular at the integrator 19. The control signal 28 is provided at the current driver 6. Furthermore, an emitter current 22 is generated at the current driver 6a, 6b, and the emitter 5a, 5b is supplied with the emitter current 22. The emitter current 22 is tapped at the measuring resistor 20. In addition, a voltage with an offset parameter 30 (corresponding to the measured voltage with an offset parameter 26) is supplied to the instrumentation amplifier 21. This specific voltage is compared with the set voltage of an input 31 (corresponding to the digital-to-analog converter voltage 23). The control signal 28 (corresponding to the integrator voltage 24) is adjusted depending upon the comparison in order to compensate for a measured error 33 and to align the measurement value 34 (corresponding to the measuring resistor voltage 27) with the set voltage 31.

Advantageously, a target temperature and/or a target current value can be defined by a user and entered into the controller 13 via the UART interface 14. The controller 13 transmits the target temperature and/or the target current value to the TEC systems 4 and to the current drivers 6a, 6b via control signals 17 and via external digital-to-analog converters.

Software which decodes and processes the received inputs and information can be used on a PC to execute the process.

FIG. 4 shows a first embodiment of a beam path of the two emitted light beams 15a, 15b from FIG. 1. After the emitted light beams 15a, 15b have left the housing 3, they enter beam guidance optics in which the second light beam 15b is reflected by a mirror 35. The mirror 35 is oriented at 45 degrees to the emission direction of the second light beam 15b and reflects the second light beam 15b after hitting the mirror 35 at a 90° angle, as shown in FIG. 4. The first light beam 15a passes through the beam guidance optics without deflection and therefore retains its original emission direction. After the second light beam 15b is deflected by 90 degrees, it crosses the first light beam 15a. These intersecting light beams 15a, 15b are used in particular in one exemplary embodiment of the atomic gyroscope.

FIG. 5 shows an alternative setup of a second exemplary embodiment of a beam path with three mirrors, in which the first light beam 15a is deflected by 90 degrees on a first mirror 35a relative to its original emission direction. The second light beam 15b is deflected by a second mirror 35b at a 90-degree angle to its original emission direction and then hits a third mirror 35c, which mirror is arranged symmetrically to a plane perpendicular to the direction of the 90-degree deflected beam path of the second light beam 15b, and is thus at a 45-degree angle in the direction of the second light beam 15b striking it. At the third mirror 35c, the incoming second light beam 15b is thus deflected again by 90 degrees and is therefore guided through the beam guidance optics in a direction opposite to the original emission direction. The third mirror 35c is offset and spaced apart from the second mirror 35c in an X-direction X. Furthermore, the second mirror 35b is offset and spaced apart from the first mirror 35a in the X-direction X, wherein the distance in the X-direction X between the first mirror 35a and the second mirror 35b is smaller than the distance between the third mirror 35c and the second mirror 35b.

After the deflections described above due to the reflections at the mirrors 35a, 35b, 35c, the first light beam 15a crosses the second light beam 15b. These intersecting light beams 15a, 15b are used in particular in another exemplary embodiment of the atomic gyroscope.

The features described or shown in the foregoing description, the claims, the exemplary embodiments, and the figures may be important individually or in any combination for realizing the various embodiments of the invention. Upon reading the present disclosure, further modifications of the invention, which are customary in the field, are suggested. Such modifications may include other features already known from the prior art, which may be used instead of or in addition to the features already described herein. Modifications of the disclosed invention and its embodiments can be understood and implemented with reference to the drawings, the disclosure, and the claims.

List of reference signs

| | | |
|---|---|---|
| 1 | Emitter device | 1 |
| 2 | Circuit board | 2 |
| 2a | First circuit board | 2a |
| 2b | Second circuit board | 2b |
| 3 | Housing | 3 |
| 4 | TEC system | 4 |
| 4a | First TEC system | 4a |
| 4b | Second TEC system | 4b |
| 5 | Emitter | 5 |
| 5a | First emitter | 5a |
| 5b | Second Emitter | 5b |
| 6 | Current driver | 6 |
| 6a | First current driver | 6a |
| 6b | Second current driver | 6b |
| 7 | Circuit board voltage source | 7 |
| 8 | Conductor | 8 |
| 9 | Voltage source | 9 |
| 10 | Power connection | 10 |
| 11a | Thermal contact | 11a |
| 11b | Thermal contact | 11b |
| 12a | DC conductor | 12a |
| 12b | DC conductor | 12b |
| 13 | Controller | 13 |
| 14 | Serial interface | 14 |
| 15a | First light beam | 15a |
| 15b | Second light beam | 15b |
| 16a | First conductor track | 16a |
| 16b | Second conductor track | 16b |
| 16c | Third conductor track | 16c |
| 16d | Fourth conductor track | 16d |
| 16e | Fifth conductor track | 16e |
| 17 | Control signal | 17 |
| 17a | First control signal path | 17a |
| 17b | Second control signal path | 17b |
| 17c | Third control signal path | 17c |
| 17d | Fourth control signal path | 17d |
| 18 | Control loop | 18 |
| 19 | PID controller | 19 |
| 20 | Measuring resistor | 20 |
| 21 | Instrumentation amplifier | 21 |
| 22 | Emitter current | 22 |
| 23 | Digital-to-analog converter voltage | 23 |
| 24 | Integrator voltage | 24 |
| 25 | Current driver voltage | 25 |
| 26 | Measuring resistor voltage with offset parameter | 26 |
| 27 | Measuring resistor voltage | 27 |
| 28 | Control signal | 28 |
| 29 | Control signal generator | 29 |
| 30 | Voltage with offset parameter | 30 |
| 31 | Input | 31 |
| 32 | Determination | 32 |
| 33 | Measured error | 33 |
| 34 | Measurement value | 34 |
| 35 | Mirror | 35 |
| X | X-direction | X |

1-15. (canceled)

16. An emitter device comprising:
a plurality of emitters configured to emit light;
a plurality of current drivers configured to provide electric current to at least one of the emitters;
a plurality of thermoelectric cooling (TEC) systems configured to regulate a temperature of at least one of the emitters and at least one of the current drivers; and
wherein each emitter is associated with at least one current driver and at least one TEC system.

17. The emitter device of claim 16, further comprising:
a plurality of circuit boards, wherein each emitter and the current driver and TEC system associated with that emitter are arranged on a corresponding circuit board.

18. The emitter device of claim 16, wherein at least one TEC system is arranged in thermal contact with at least one emitter and at least one current driver.

19. The emitter device of claim 18, wherein the at least one TEC system is arranged in thermal contact with exactly one emitter and exactly one current driver.

20. The emitter device of claim 16, wherein the TEC systems are configured to maintain the temperature of the current drivers or the emitters substantially constant.

21. The emitter device of claim 17, further comprising:
a circuit board voltage source arranged on or with a first circuit board.

22. The emitter device of claim 21, wherein the circuit board voltage source is configured to supply current to all of the TEC systems and all of the current drivers.

23. The emitter device of claim 17, further comprising:
a controller arranged on or with a second circuit board.

24. The emitter device of claim 23, wherein the circuit board voltage source of claim 21 is configured to supply current to the controller.

25. The emitter device of claim 23, wherein the controller includes or is connected to a serial interface.

26. The emitter device of claim 25, wherein the controller is configured to control all of the TEC systems and all of the current drivers.

27. The emitter device of claim 17, wherein the circuit boards are arranged within a common housing.

28. A gyroscope comprising the emitter device of claim 16.

29. A control loop for an emitter device comprising an emitter and a current driver, the control loop comprising:
a proportional-integral-derivative controller;
a measuring resistor; and
an instrumentation amplifier;
wherein the current driver is arranged between the proportional-integral-derivative controller and the measuring resistor and is electrically connected to both; and
wherein the instrumentation amplifier is arranged between the proportional-integral-derivative controller and the measuring resistor and is electrically connected to both.

30. A method for operating the control loop of claim 29, the method comprising:
providing the control loop;
arranging the measuring resistor between the current driver and the instrumentation amplifier;
setting a reference voltage;
generating a control signal at the proportional-integral-derivative controller;
providing the control signal to the current driver;
generating an emitter current at the current driver;
applying the emitter current to the emitter;
tapping the emitter current at the measuring resistor;
providing voltage to the instrumentation amplifier;
determining a voltage at the instrumentation amplifier;
comparing the determined voltage with the reference voltage; and
adjusting the control signal based on the comparison.
